(19) United States
(12) Patent Application Publication
(10) Pub. No.: US 2003/0036284 A1
(43) Pub. Date: Feb. 20, 2003

(54) Method for removing the photoresist layer of ion-implanting process

(76) Inventors: Yu-Ren Chou, Hsin-Chu City (TW); Jing-Hung Liu, Taipei (TW)

Correspondence Address: POWELL, GOLDSTEIN,, FRAZER & MURPHY LLP, P.O. BOX 97223, WASHINGTON, DC, 20090-7223, US

(21) Appl. No.: 09/930,853

(22) Filed: Aug. 16, 2001

(51) Int. Cl. H01L 21/302; H01L 21/461

(52) U.S. Cl. 438/710

(57) ABSTRACT

First of all, a semiconductor substrate is provided. Then a photoresist layer is formed on the semiconductor substrate, and the photoresist layer is defined to form a pre-region. Afterward, an ion-implanting process is performed by using the photoresist layer as an ion-implanting mask to form an ion-implanting region in the semiconductor substrate of the pre-region. Because the surface of the photoresist layer is bombarded with ions, a hard mask is formed on the photoresist layer. Subsequently, an etching process with fluorine-based plasma is performed to strip the hard mask. An ashing process with the temperature about, but more than 250° C. is performed by way of an oxide plasma process to remove the photoresist layer. Finally, a soak process with a sulfuric acid and a cleaning process with the RAC are performed to remove the remainder of the photoresist layer.

### BACKGROUND OF THE INVENTION

1. Field of the Invention

The present invention relates generally to a method for removing the photoresist layer, and in particular to a process for stripping the photoresist layer that is used in the ion-implanting process.

2. Description of the Prior Art

As semiconductor devices, such as Metal-Oxide-Semiconductor devices, become highly integrated the area occupied by the device shrinks, as well as the design rule. With advances in the semiconductor technology, the dimensions of the integrated circuit (IC) devices have shrunk to the deep sub-micron range. When the semiconductor device continuously shrinks to the deep sub-micron region, some problems described below are incurred due to the process of scaling down.

Cross-sectional views of a process for performing an ion-implantation of the known prior art are illustrated in FIG. 1A. First of all, a semiconductor substrate 100 is provided. Then a photoresist layer 110 on the semiconductor substrate 100 and the photoresist layer 110 is defined to form a pre-region 120. Afterwards, by using the photoresist layer 110 to form an ion-implanting region 130 in the semiconductor substrate 100 of the pre-region 120 performs an ion-implanting process 140. Because the surface of the photoresist layer 110 is bombarded with ions, a hard mask 150 is formed on the photoresist layer 110. Finally, an ashing process of the oxide plasma with a temperature over 250° C. is performed to remove the photoresist layer 110 and the hard mask 150 in a cleaning process of RCA thereof.

Nevertheless, some issues still exist in the above processes. When the ion-implanting process 140 is performed, surface variations i.e. characteristic and hardness of the photoresist layer 110 will depend on the dosage of the ion-implantation, . In general, the average dose of ion-implantation is about E12 to E13, the high dose is around E14 to E15, and an ultra high dosage is more than E16. The dosage effects the hardness of the hard mask 150 on the photoresist layer 110, which increases along with the dosage of ion-implantation. As a result, as shown in FIG. 1B, the above process does not entirely strip the photoresist layer 110 on the semiconductor substrate 100,. The remainder of the photoresist layer is difficult to remove by way of a conventional process. Furthermore, as shown in FIG. 1C, the photoresist layer 110 contains an evaporative solvent that enters the hard mask 150 during the high temperature ashing process. The evaporative solvent forms a convex coke that expands and severely hardens the hard mask 150. Therefore, if the photoresist layer 110 and the hard mask 150 are directly stripped from the semiconductor substrate 100 serious damage will occur. The conventional process will be hard to perform in the deep sub-micron technology particularly the method for removing the photoresist layer becomes more complex, and wastes time, hence, an increase in cost.

In accordance with the above description, a new and improved method for removing the photoresist layer is therefore necessary so as to raise the yield and quality of the follow-up process.

### SUMMARY OF THE INVENTION

In accordance with the present invention, a method is provided for stripping the photoresist layer that substantially overcomes the drawbacks of the above mentioned problems that arise from conventional methods.

Accordingly, it is a main object of the present invention to provide a method for stripping the photoresist layer. After the ion-implantation is finished, this invention can use an etching process to remove the hard mask on the photoresist layer in advance and then perform the follow-up ashing process with oxide plasma to entirely remove the photoresist layer. Furthermore, the etching process of the present invention uses a fluorine-based plasma process with an operational temperature just under 100° C. Wherein the operational temperature of the fluorine-based plasma process can be increased slowly so as to avoid the solvent from evaporating into the hard mask, further, the hard mask is entirely stripped by way of the etching process of the fluorine-based plasma. Therefore, the present invention reduces the complexity of the conventional semiconductor process, which makes it appropriate for deep sub-micron technology and cost reductions that correspond to economic effect.

In accordance with the present invention, a new method for removing the photoresist layer is disclosed. First of all, a semiconductor substrate is provided. Then a photoresist layer is formed on the semiconductor substrate, and the photoresist layer is defined to form a pre-region. Afterward, an ion-implanting process is performed by using the photoresist layer as an ion-implanting mask to form an ion-implanting region in the semiconductor substrate of the pre-region. Because the surface of the photoresist layer is bombarded with ions, a hard mask is formed on the photoresist layer. Subsequently, a fluorine-based plasma etching process is performed to strip the hard mask. An ashing process with the temperature more than 250° C. is performed by way of an oxide plasma process to remove the photoresist layer. Finally, a soaking process with a sulfuric acid and a cleaning process with the RAC are performed to remove the remainder of the photoresist layer.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A shows cross-sectional views illustrative of removing the photoresist layer in accordance with the conventional process;

FIG. 1B shows cross-sectional views illustrative of forming a remainder in accordance with the conventional process for removing the photoresist layer;

FIG. 1C shows cross-sectional views illustrative of forming a convex hard mask in accordance with the conventional process for removing the photoresist layer;

FIG. 2A and FIG. 2B show cross-sectional views illustrative of various stages for removing the photoresist layer by way of a etching process of plasma in accordance with the first embodiment of the present invention;

FIG. 3A and FIG. 3B show cross-sectional views illustrative of various stages for removing the photoresist layer by way of a etching process of plasma and an ashing process of plasma in accordance with the second embodiment of the present invention; and

FIG. 3C shows a flowchart illustrative of various stages for removing the photoresist layer in accordance with the second embodiment of the present invention.

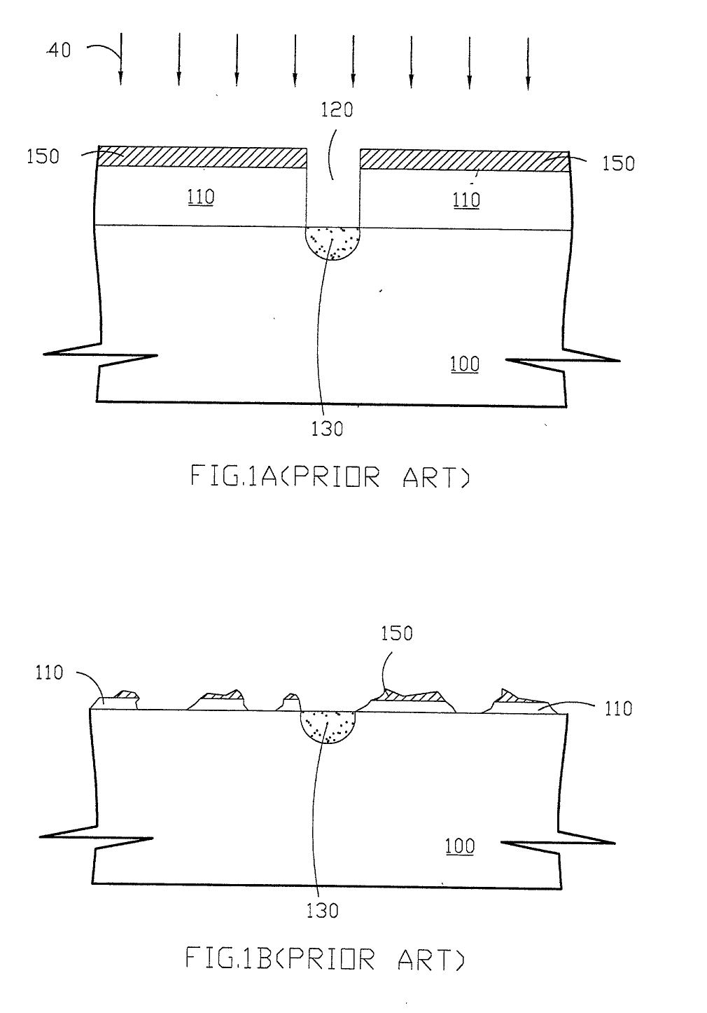

### DESCRIPTION OF THE PREFERRED EMBODIMENT

Preferred embodiments of the present invention will now be described in greater detail. Nevertheless, it should be recognized that the present invention can be practiced in a wide range of embodiments besides those explicitly described, and the scope of the present invention is expressly not limited except as specified in the accompanying claims.

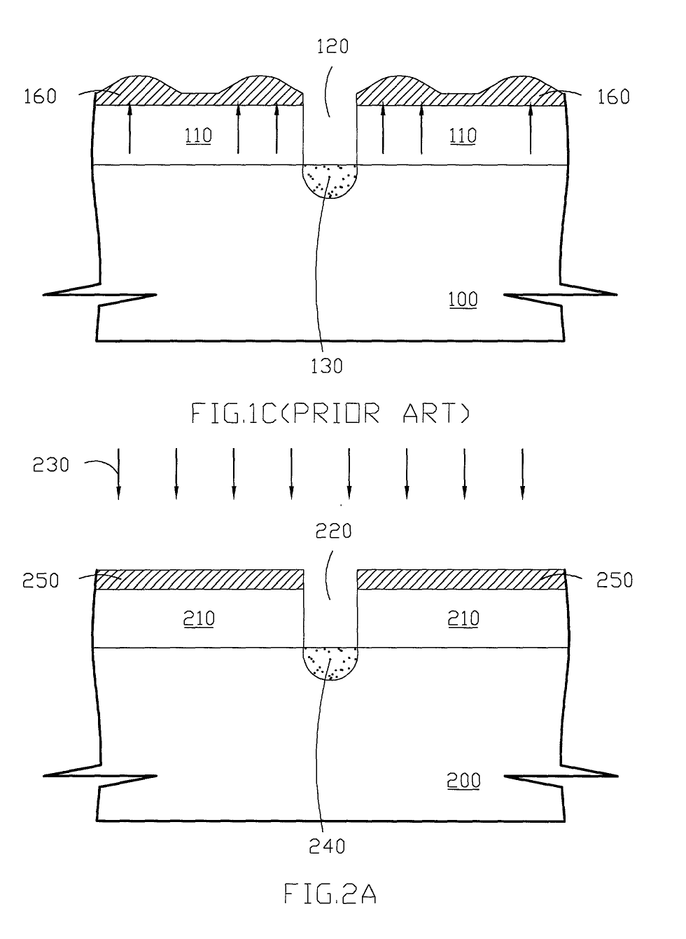

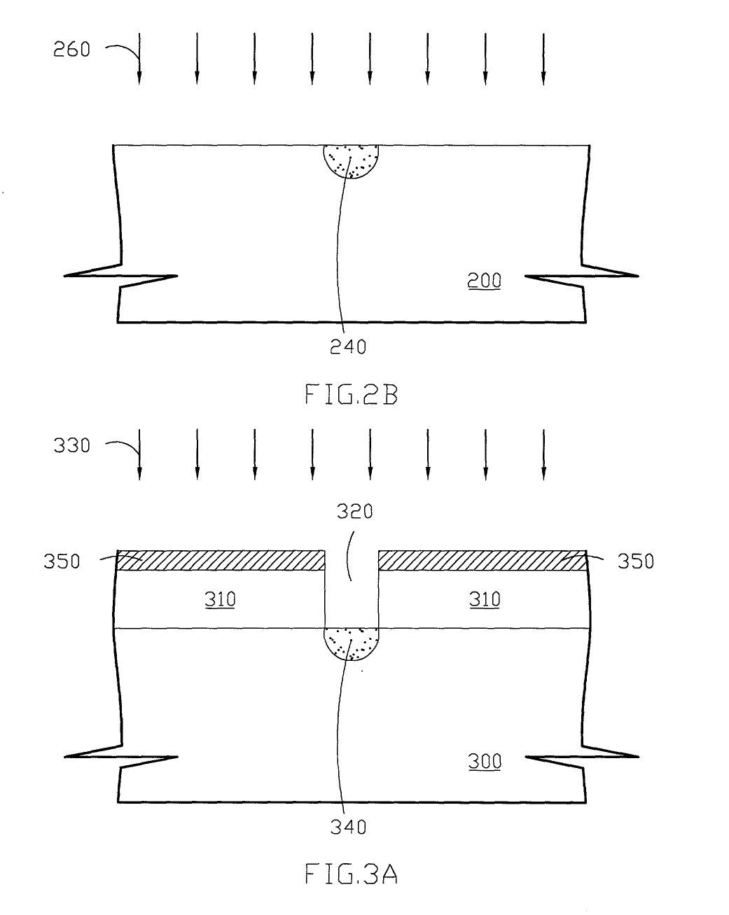

As illustrated in FIG. 2A, in the first embodiment of the present invention, a semiconductor substrate 200 is provided. Then a photoresist layer 210 is formed on the semiconductor substrate 200, which is defined to form a pre-region 220. Afterward, an ion-implanting process 230 is performed by using the photoresist layer 210 as an ion-implanting mask to form an ion-implanting region 240 in the semiconductor substrate 200 of the pre-region 220. Because the surface of the photoresist layer 210 is bombarded with ions, a hard mask 250 is formed on the photoresist layer 210. Subsequently, a process 260 for removing the photoresist layer is performed to entirely strip the hard mask 250 and photoresist layer 210. As shown in FIG. 2B, the process 260 for removing , the photoresist layer comprises an etching process with plasma, and the etchant of the etching process comprises a fluorine-based gas, such as CF4, with an operational temperature less than 100° C.,

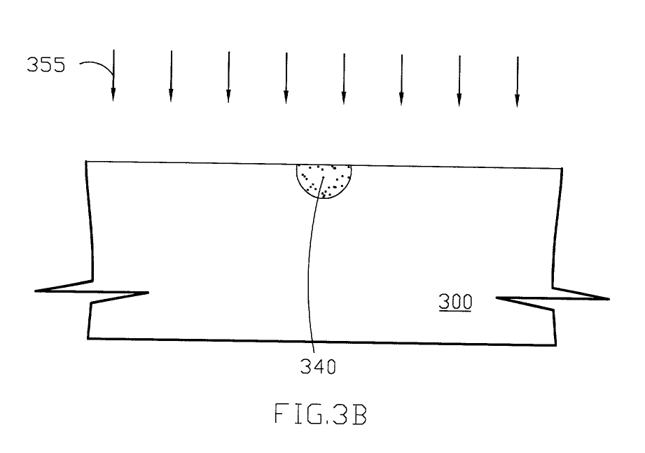

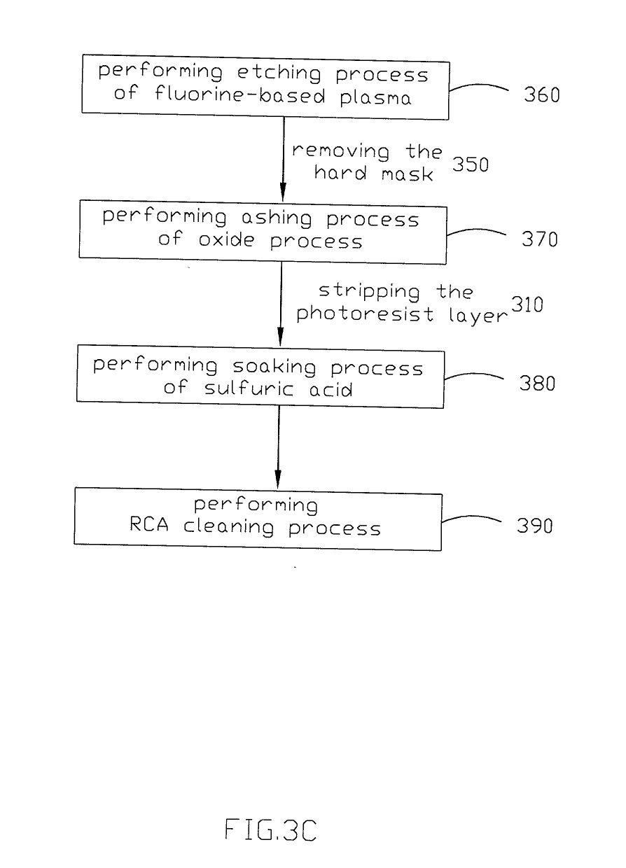

As illustrated in FIG. 3A, in the second embodiment of the present invention, a semiconductor substrate 300 is provided. Then a photoresist layer 310 is formed on the semiconductor substrate 300 and photoresist layer 310 is defined to form a pre-region 320. Afterward, an ion-implanting process 330 is performed by using the photoresist layer 310 as an ion-implanting mask to form an ion-implanting region 340 in the semiconductor substrate 300 of the pre-region 320, wherein ion-implanting process 330 comprises a dosage around but more then E16. Because the surface of the photoresist layer 310 is bombarded with ions, a hard mask 350 is formed on the photoresist layer 310.

As illustrated in FIG. 3B and FIG. 3C, in the second embodiment of the present invention, a process 355 to remove the photoresist layer is performed to entirely strip the hard mask 350 and photoresist layer 310. The process 355 for removing the photoresist layer comprises: an etching process 360 of fluorine-based plasma used to strip the hard mask 350 on the photoresist layer 310 in advance, wherein the operational temperature of the etching process 360 is about but less than 100° C., and the etchant of etching process 360 comprises a gas that consists fluorine and carbon; subsequently, an ashing process 370 of an oxide plasma is performed to remove the photoresist layer 310, wherein the temperature of the ashing process 370 is about but more than 250° C.; a soaking process 380 with a sulfuric acid and a RAC cleaning process 390 is performed to remove the remainder of the photoresist layer 310.

In these embodiments of the present invention, as discussed above, after the ion-implantation is finished, this invention can use an etching process to remove the hard mask on the photoresist layer in advance, and then perform follow-up ashing process with oxide plasma to entirely remove the photoresist layer. Furthermore, the etching process of the present invention uses a fluorine-based plasma process, and the operational temperature of the fluorine-based plasma process is about but less than 100° C., wherein the operational temperature of the fluorine-based plasma process can be increased slowly, so as to avoid evaporation of the solvent into the hard mask, further, the hard mask is entirely stripped by way of the etching process of the fluorine-based plasma. Therefore, the present invention reduces the complexity of the conventional semiconductor process, which makes it appropriate for deep sub-micron technology and cost reductions that correspond to economic effect.

Of course, it is possible to apply the present invention to strip the photoresist layer of the ion-implantation, and to any process for removal of the photoresist layer in the semiconductor devices. Also, this invention can be applied to strip the hard mask on the photoresist layer by the plasma etching process concerning fluorine-based plasma process used for removing the photoresist layer has not been developed at present. The method of the present invention is the best process for removing the photoresist layer compatible process for deep sub-micro process.

Obviously, many modifications and variations of the present invention are possible in light of the above teachings. It is therefore to be understood that within the scope of the appended claims, that the present invention may be practiced other than as specifically described herein.

Although the specific embodiments have been illustrated and described, it will be obvious to those skilled in the art that various modifications may be made without departing from what is intended to be limited solely by the appended claims.

What is claimed is:

1. A method for stripping a photoresist layer, the method comprising:
providing a semiconductor substrate;
forming a photoresist layer on said semiconductor substrate;
performing an ion-implanting process by way of using said photoresist layer as an ion-implanting mask to form an ion-implanting region in said semiconductor substrate, and forming a hard mask on said photoresist layer; and
performing a removing process having a etching process of plasma to strip said hard mask and said photoresist layer.

2. The method according to claim 1, wherein the dosage of said ion-implanting process comprises a concentration about more than E16.

3. The method according to claim 1, wherein the etchant of said etching process of plasma comprises a fluorine-based gas.

4. The method according to claim 3, wherein said fluorine-based gas comprises a CF₄.

5. The method according to claim 1, wherein said etching process of plasma comprises an operational temperature about more than 100° C.

6. A method for stripping a photoresist layer, the method comprising:
providing a semiconductor substrate;
forming a photoresist layer on said semiconductor substrate;
performing an ion-implanting process by way of using said photoresist layer as an ion-implanting mask to form an ion-implanting region in said semiconductor substrate, and forming a hard mask on said photoresist layer;
performing an etching process of fluorine-based plasma to strip said hard mask
performing an ashing process to strip said photoresist layer; and
performing a cleaning process to clean said semiconductor substrate.

7. The method according to claim 6, wherein the dosage of said ion-implanting process comprises a concentration about more than E16.

8. The method according to claim 6, wherein said etching process of fluorine-based plasma comprises a gas that consists of a fluorine and a carbon.

9. The method according to claim 6, wherein said etching process of fluorine-based plasma comprises an operation temperature about less than 100° C.

10. The method according to claim 6, wherein said ashing process comprises an oxide process.

11. The method according to claim 6, wherein said ashing process comprises a temperature about more than 250° C.

12. The method according to claim 6, wherein said cleaning process comprises a soaking process with a sulfuric acid.

13. The method according to claim 6, wherein said cleaning process comprises a RAC cleaning process.

14. A method for removing a photoresist layer, the method comprising:
providing a semiconductor substrate, wherein said semiconductor substrate has a photoresist layer thereon;
performing an ion-implanting process with a dosage about more than E16 by way of using said photoresist layer as an ion-implanting mask to form an ion-implanting region in said semiconductor substrate, and forming a hard mask on said photoresist layer;
performing an etching process of fluorine-based plasma with an operational temperature about less than 100° C. to strip said hard mask;
performing an ashing process of oxide plasma to strip said photoresist layer; and
performing a cleaning process to clean said semiconductor substrate.

15. The method according to claim 14, wherein said etching process of fluorine-based plasma comprises a gas that consists of a fluorine and a carbon.

16. The method according to claim 14, wherein said ashing process of oxide plasma comprises a temperature about more than 250° C.

17. The method according to claim 14, wherein said cleaning process comprises a soaking process with a sulfuric acid.

18. The method according to claim 14, wherein said cleaning process comprises a RAC cleaning process.
